(19) United States
(12) Patent Application Publication
(10) Pub. No.: US 2025/0203996 A1
(43) Pub. Date: Jun. 19, 2025

(54) SEMICONDUCTOR DEVICE AND METHOD FOR FABRICATING A SEMICONDUCTOR DEVICE

(71) Applicant: Renesas Electronics Corporation, Tokyo (JP)

(72) Inventor: Yukio MAKI, Tokyo (JP)

(21) Appl. No.: 18/931,202

(22) Filed: Oct. 30, 2024

(30) Foreign Application Priority Data
Dec. 15, 2023 (JP) 2023-212241

(51) Int. Cl. H01L 29/417; H01L 21/285; H01L 29/40; H01L 29/45; H01L 29/66; H01L 29/78

(52) U.S. Cl. CPC H10D 64/252; H01L 21/28518; H10D 30/0295; H10D 30/0297; H10D 30/668; H10D 64/117; H10D 64/62

(57) ABSTRACT

A semiconductor device includes: a semiconductor layer having an N type drift region, a P type body region on the N type drift region, and an N type source region on the P type body region; an insulating layer on the semiconductor layer; a first opening provided in the insulating layer; a second opening provided in the semiconductor layer and extending from the N type source region to the P type body region so as to overlap the first opening in plan view; an insulating film arranged on a sidewall of the second opening; a first metal layer provided on the insulating layer, on the semiconductor layer of the first opening, on the insulating film, and on the semiconductor layer of the second opening; and a second metal layer provided on the first metal layer.

### CROSS-REFERENCE TO RELATED APPLICATIONS

The disclosure of Japanese Patent Application No. 2023-212241 filed on Dec. 15, 2023 including the specification, drawings and abstract is incorporated herein by reference in its entirety.

### BACKGROUND

The present disclosure relates to a semiconductor device and a method for fabricating a semiconductor device.

There are disclosed techniques listed below.

[Patent Document 1] Japanese Unexamined Patent Application Publication No. 2008-42056

A technique for miniaturizing a semiconductor device is being developed.

However, when fabricating an electrode, there was a problem in which a barrier metal breaks, causing a semiconductor layer and the material forming the electrodes to react.

Other problems and novel features will become apparent from the description of the present specification and accompanying drawings.

### SUMMARY

According to one embodiment, a semiconductor device has a structure in which sidewalls of a source region and a body region are covered with an insulating film to prevent reaction with electrodes.

According to the embodiment, it is possible to provide a highly reliable semiconductor device.

### BRIEF DESCRIPTION OF THE DRAWINGS

FIG. 1 includes drawings showing a method for fabricating an electrode of a semiconductor device of a related art.

FIG. 2 includes drawings showing a method for fabricating an electrode of a semiconductor device of the present disclosure.

FIG. 3 is a schematic view of the semiconductor device of the present disclosure.

FIG. 4 is a schematic view of another semiconductor device of the present disclosure.

FIG. 5 includes drawings showing a method for fabricating the semiconductor device of the present disclosure.

### SUMMARY

### Embodiments

In the following, embodiments of the present invention will be described with reference to the drawings. However, the present invention according to the claims is not limited to the following embodiments. In addition, not all configurations described in the embodiments are necessarily required as a means to solve the problem. For the sake of clarity of explanation, the following descriptions and drawings have portions omitted or simplified as appropriate. In each drawing, identical elements are denoted by an identical reference sign, and redundant descriptions thereof are omitted as appropriate.

### Semiconductor Device According to First Embodiment

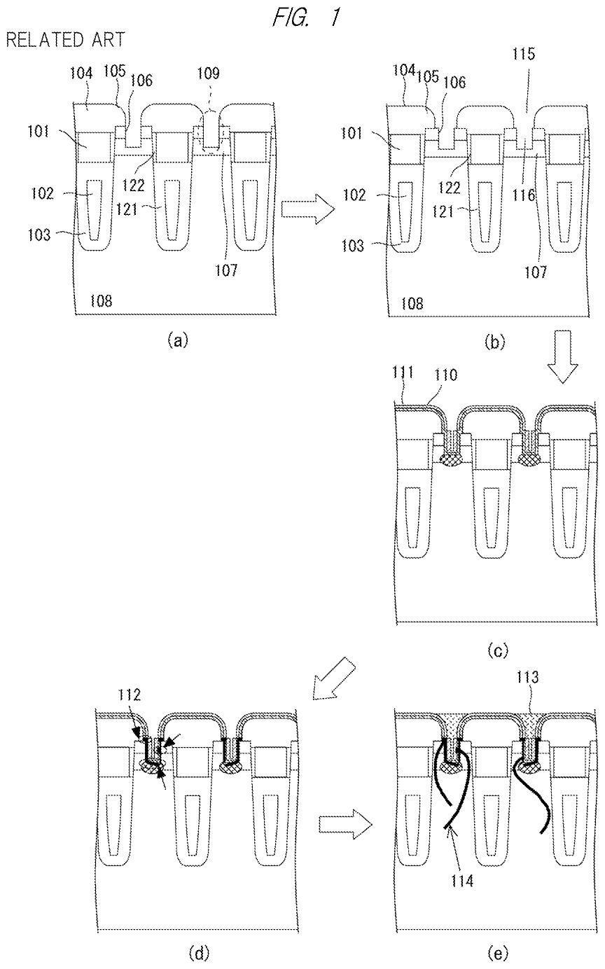

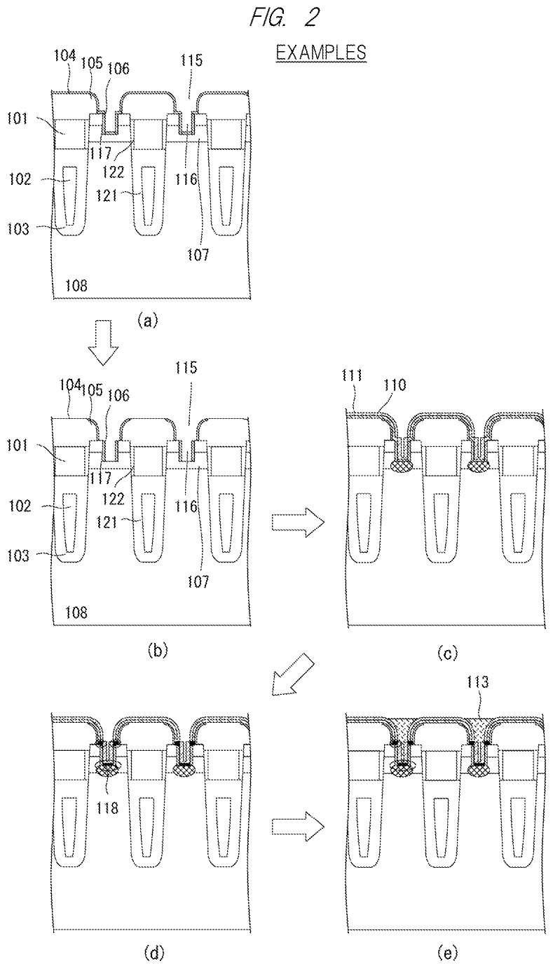

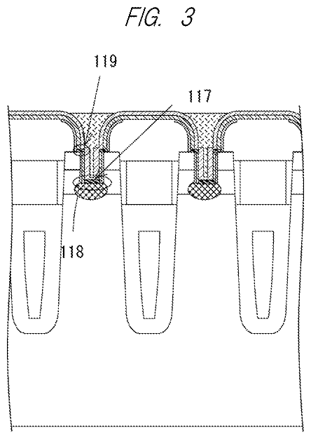

FIG. 1 includes drawings showing a method for fabricating an electrode of a semiconductor device of a related art. FIG. 2 includes drawings showing a method for fabricating an electrode of a semiconductor device of the present disclosure. FIG. 3 is a schematic view of the semiconductor device of the present disclosure. Hereinafter, the semiconductor device according to the first embodiment will be described with reference to FIGS. 1 to 3.

As shown in (a) of FIG. 1, the semiconductor device of the related art comprises a semiconductor layer including an N type drift region 108, a P type body region 107 on the N type drift region 108, and an N type source region 106 on the P type body region 107. The semiconductor device is provided on a semiconductor substrate such as, for example, a silicon substrate, and the semiconductor layer uses a composition of the semiconductor substrate. A trench is formed in the semiconductor layer, and an embedded insulating film 103, a shield electrode 102, and a gate electrode 101 are embedded in the trench. An insulating layer 104 is formed on the semiconductor layer. A sidewall of the insulating layer 104 is provided with a sidewall 105 for self-align contact (SAC-SW). In the present specification, the insulating layer 104 may include the SAC-SW.

A drain electrode is formed below the N type drift region 108, and current flows through the semiconductor layer so as to vertically penetrate the semiconductor layer. The semiconductor layer is made of, for example, silicon (Si). The semiconductor device is a so-called power metal-oxide-semiconductor (power MOS) or a metal insulator semiconductor (MIS). The power MOS is a semiconductor device that functions as a switch or a control element when a voltage is applied to a gate to form a channel between a source and a drain in which a relatively large current flows.

The N type drift region 108 is formed as an N type to allow a flow of electrons. The P type body region 107 forms a channel and allows the electrons to flow when the semiconductor device is turned on and a positive voltage is applied to the gate electrode 101. A small amount of P type impurities such as boron (B) is introduced into the P type body region 107. The N type source region 106 injects electrons when the semiconductor device is turned on. N type impurities are introduced into the N type source region 106. The N type source region 106 has more N type impurities than the N type drift region 108.

For example, the semiconductor device according to the above-described embodiment may have a configuration in which conductivity types (P type or N type) of a semiconductor substrate, semiconductor layer, diffusion layer (diffusion region), or the like are inverted. Therefore, when one of the N type and P type conductivity type is a first conductivity type and the other conductivity type is a second conductivity type, the first conductivity type can be the P type, and the second conductivity type can be the N type, or conversely, the first conductivity type can be the N type and the second conductivity type can be the P type.

The embedded insulating film 103 is formed to insulate the shield electrode 102 and the gate electrode 101 from the semiconductor layer. The embedded insulating film 103 may function as a field plate insulating film 121 and a gate insulating film 122. The embedded insulating film 103 on a side surface of the shield electrode 102 functions as the field plate insulating film 121, and the embedded insulating film 103 on a side surface of the gate electrode 101 functions as the gate insulating film 122.

The gate electrode 101 is made of, for example, polysilicon. Applying a voltage to the gate electrode 101 allows the semiconductor device to control a current flow between the source and the drain. The shield electrode 102 is an electrode to which a ground potential or the same voltage as the gate electrode may be applied. The shield electrode 102 is made of polysilicon. The shield electrode 102 assists in controlling the semiconductor device.

An SAC 109 is a technique for forming electrodes by introducing impurities in a self-aligned manner. The SAC 109 allows elements to be miniaturized beyond the limits of photolithography. Here, it is used to form a second opening 116 in the N type source region 106. A source electrode is formed in the second opening 116. Therefore, the second opening 116 is formed so as to penetrate the N type source region 106 and extend to the middle of the P type body region 107.

As shown in (b) of FIG. 1, the SAC-SW 105 is withdrawn by performing wet-etching to form a first opening 115 in the insulating layer 104. In this process, the silicon on the source region 106 is exposed.

As shown in (c) of FIG. 1, P type impurities such as boron are introduced into the opening at a high concentration. In order to obtain an ohmic connection, a first metal layer made of titanium (Ti) 110 is formed, and a barrier metal made of titanium nitride (TiN) 111 is formed on the first metal layer.

As shown in (d) of FIG. 1, heat treatment is performed in this state, and the first metal layer reacts with the semiconductor layer, forming a silicide. In particular, when the first metal layer is titanium, a titanium silicide is formed.

With device miniaturization, cohesion 112 of the titanium silicide occurs. The cohesion of the titanium silicide occurs at a side surface of the semiconductor layer and at a bottom portion of the N type source region 106 and the P type body region 107 depending on titanium silicide formation conditions. Since a titanium film thickness differs between a sidewall portion and the bottom portion of the N type source region 106 and the P type body region 107, the degree of titanium silicide cohesion differs, causing stress to occur. Therefore, the barrier metal made of the titanium nitride 111 of a sidewall of the semiconductor layer breaks.

Then, as shown in (e) of FIG. 1, when a tungsten (W) plug 113 which is a second metal layer is embedded in the opening using tungsten fluoride, fluorine enters from the sidewall of the semiconductor layer not covered by the barrier metal and reacts with the semiconductor layer, causing a wormhole 114 to form.

The semiconductor device of the present disclosure is a technique provided to prevent such a wormhole 114. Details of this technique until the formation of the SAC 109 are omitted, as the process is the same as FIG. 1. As shown in (a) of FIG. 2, after the second opening 116 for embedding the source electrode in the insulating layer 104 and the semiconductor layer is formed, the SAC-SW 105 is withdrawn. Withdrawing the SAC-SW 105 allows the first opening 115 overlapping the second opening 116 in plan view to be formed in the insulating layer 104 and the sidewall. The first opening 115 overlapping the second opening 116 in plan view is formed in the insulating layer 104 and the sidewall. Then, an insulating film 117 is arranged in the first opening 115 and the second opening 116.

Next, as shown in (b) of FIG. 2, the insulating film 117 on an upper surface of the semiconductor layer is removed by performing anisotropic etching while the insulating film 117 on the side surface of the semiconductor layer is left as is to form the insulating film 117 on the sidewall of the semiconductor layer.

A silicon oxide film, a silicon nitride film, a silicon oxynitride film, or a laminated layer of such films can be used for the insulating film 117. The insulating film 117 may be the same silicon oxide film as the SAC-SW. Using the silicon nitride film for the insulating film 117 allows subsequent processing without reducing a thickness of the film, making it possible to reduce the thickness of the film. Forming the insulating film 117 to be a multilayer structure including the silicon oxide film and the silicon nitride film makes it possible to mitigate reduction in the thickness of the film and stress caused by the silicon nitride film.

Then, as shown in (c) of FIG. 2, P type impurities such as boron are injected into the second opening 116 at a high concentration to provide the titanium which is the first metal layer and the titanium nitride which is the barrier metal. Titanium of the first metal layer is reacted with the silicon (Si) of the semiconductor layer to form titanium silicide 118 on an upper surface of the source region and an upper surface of the P type body region.

As shown in (d) of FIG. 2, at the sidewall of the semiconductor layer, the insulating film 117 and the titanium are in contact but the titanium and the silicon are not in contact, so that no titanium silicide is formed and no cohesion 112 occurs. The titanium which is the first metal layer reacts with only the silicon on the upper surface of the semiconductor layer where it contacts the semiconductor layer.

As shown in (e) of FIG. 2, when tungsten which is the second metal layer is embedded, no stress due to the difference in cohesion occurs, so that the barrier metal does not break and no wormhole is formed. In this manner, a highly reliable semiconductor device can be obtained.

As shown in FIG. 3, a silicide 119 is formed on an upper surface of the N type source region, and a silicide 118 is formed on the upper surface of the P type body region. At the side surface of the N type source region 106 and the side surface of the P type body region 107, the insulating film 117 and the first metal layer 110 are in contact but the first metal layer 110 and the semiconductor layer are not in contact, so that no silicide is formed, and no cohesion 112 and no stress due to the difference in cohesion occur.

Here, the titanium is used for the first metal layer. However, cobalt (Co) may also be used. The same titanium nitride is used for the barrier metal. By using cobalt, wires can be made finer and an increase in resistance due to cohesion can be suppressed. When cobalt is used, the first metal layer is formed before introducing P type impurities into the second opening. It is preferable to introduce P type impurities after a cobalt silicide is formed to suppress a spike generation in the cobalt silicide.

### Semiconductor Device According to Second Embodiment

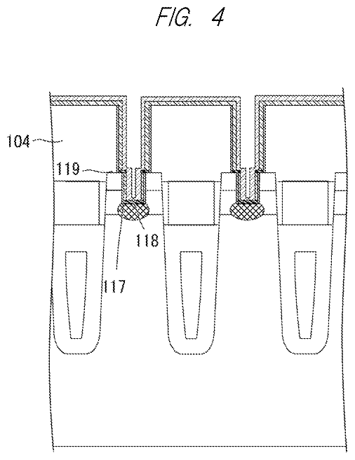

FIG. 4 is a schematic view of another semiconductor device of the present disclosure. Hereinafter, the semiconductor device according to the second embodiment will be described with reference to FIG. 4.

The semiconductor device according to the second embodiment differs from the semiconductor device according to the first embodiment in that the SAC-SW 105 is not formed. That is, in the semiconductor device according to the second embodiment, an opening is formed in the insulating layer 104 using conventional photolithography.

As shown in FIG. 4, the insulating film 117 is formed on the sidewall of the insulating layer 104 and the sidewall of the semiconductor layer. Therefore, in the semiconductor device according to the second embodiment, the barrier metal does not break and no wormhole is formed. In addition, the insulating film is removed from the upper surface of the insulating layer 104 and the upper surface of the semiconductor layer. Therefore, in the first metal layer and the semiconductor layer, the silicide 119 is formed on the upper surface of the N type source region, and the silicide 118 is formed on the upper surface of the P type body region. In this manner, a highly reliable semiconductor device can be obtained.

### Method for Fabricating Semiconductor Device According to First Embodiment

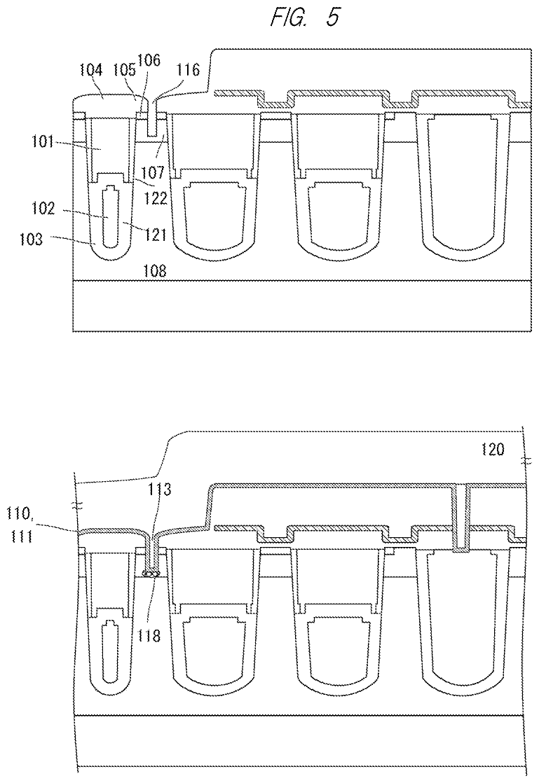

FIG. 5 includes drawings showing a method for fabricating the semiconductor device of the present disclosure. Hereinafter, the method for fabricating the semiconductor device according to the first embodiment will be described with reference to FIG. 5.

As shown in the upper drawing of FIG. 5, the semiconductor layer is formed in which the N type drift region 108, the P type body region 107 on the N type drift region 108, and the N type source region 106 on the P type body region 107 are formed. Next, the gate electrode 101, the shield electrode 102, and the embedded insulating film 103 are formed in the semiconductor layer. The embedded insulating film 103 has the field plate insulating film 121 and the gate insulating film 122. The insulating layer 104 is formed on the semiconductor layer and on the gate electrode 101. Next, the sidewall 105 is formed on the side surface of the insulating layer 104. The second opening 116 extending from the N type source region 106 to the P type body region 107 is formed in the semiconductor layer.

As shown in the lower drawing of FIG. 5, the sidewall 105 is withdrawn to form the first opening 115 in the insulating layer 104. The first opening 115 overlaps the second opening 116 in cross-sectional view. Next, the insulating film 117 is formed on the insulating on the sidewall 105, and on the semiconductor layer. Next, the insulating film 117 is removed from the semiconductor layer while the insulating film 117 on the sidewall of the semiconductor layer is left as is. The insulating film 117 is removed by using, for example, anisotropic etching.

Next, P type impurities are injected into the semiconductor layer and are activated by heat treatment. Next, the first metal layer 110 is formed on the insulating layer 104, on the sidewall 105, and on the semiconductor layer. The first metal layer 110 also covers the insulating film 117. The first metal layer 110 is, for example, a titanium-containing material, and the titanium-containing material is a laminated layer of the titanium and the titanium nitride. The titanium-containing metal layer is formed and heated to form the silicide 118 of the semiconductor layer and the titanium.

The second metal layer 113 is formed on the first metal layer 110. The second metal layer 113 is a tungsten-containing material. After the second metal layer 113 is formed, a wiring layer 120 made of aluminum-copper (Al—Cu) is formed to complete the semiconductor device.

A third metal layer may be provided between the first metal layer 110 and the second metal layer 113. For example, if cobalt is used for the first metal layer 110, the titanium-containing material is used for the third metal layer, and the tungsten-containing material is used for the second metal layer 113. After the cobalt is formed, heating is performed to form the silicide. The titanium-containing material is a laminated layer of the titanium and the titanium nitride, and acts as a barrier metal against the tungsten.

In this manner, a highly reliable semiconductor device can be obtained.

In the foregoing, the invention made by the present inventors has been described in detail based on the embodiments. However, the present invention is not limited to the above-described embodiments, and various modifications can be made without departing from the gist of the invention.

What is claimed is:

1. A semiconductor device comprising:
a semiconductor layer including an N type drift region, a P type body region on the N type drift region, and an N type source region on the P type body region;
an insulating layer on the semiconductor layer;
a first opening provided in the insulating layer;
a second opening provided in the semiconductor layer and extending from the N type source region to the P type body region so as to overlap the first opening in plan view;
an insulating film arranged on a sidewall of the second opening;
a first metal layer provided on the insulating layer, on the semiconductor layer of the first opening, on the insulating film, and on the semiconductor layer of the second opening; and
a second metal layer provided on the first metal layer.

2. The semiconductor device according to claim 1,
wherein the insulating layer includes a sidewall,
wherein the second opening is formed by the sidewall in a self-aligned manner, and
wherein the first opening is formed by withdrawing the sidewall.

3. The semiconductor device according to claim 1,
wherein the first metal layer includes titanium,
wherein the second metal layer includes tungsten, and
wherein the titanium forms a silicide in a region in contact with the semiconductor layer.

4. The semiconductor device according to claim 1,
wherein a third metal layer is provided between the first metal layer and the second metal layer,
wherein the first metal layer includes cobalt,
wherein the second metal layer includes tungsten,
wherein the third metal layer includes titanium, and
wherein the cobalt forms a silicide in a region in contact with the semiconductor layer.

5. The semiconductor device according to claim 1,
wherein a trench is provided in the semiconductor layer, and
wherein an embedded insulating film, a shield electrode, and a gate electrode are provided in the trench.

6. A method for fabricating a semiconductor device including:
forming a semiconductor layer in which an N type drift region, a P type body region on the N type drift region, and an N type source region on the P type body region are formed;
forming a field plate insulating film, a gate insulating film, a shield electrode, and a gate electrode in the semiconductor layer;
forming an insulating layer on the gate electrode and on the semiconductor layer;
forming a sidewall on a side surface of the insulating layer;
forming a second opening in the semiconductor layer, the second opening extending from the N type source region to the P type body region;
withdrawing the sidewall to form a first opening in the insulating layer, the first opening overlapping the second opening in plan view;
forming an insulating film on the insulating layer, on the sidewall, and on the semiconductor layer;
removing the insulating film on the semiconductor layer, while leaving the insulating film on the side surface of the semiconductor layer as is;
injecting P type impurities into the semiconductor layer;
activating the P type impurities;
forming a first metal layer on the insulating layer and on the semiconductor layer; and
forming a second metal layer on the first metal layer.

7. The method for fabricating a semiconductor device according to claim 6 including, after forming the first metal layer, forming a silicide by performing heating.

8. The method for fabricating a semiconductor device according to claim 7,
wherein the first metal layer includes titanium, and
wherein the second metal layer includes tungsten.

9. The method for fabricating a semiconductor device according to claim 7,
wherein a third metal layer is provided between the first metal layer and the second metal layer,
wherein the first metal layer includes cobalt,
wherein the second metal layer includes tungsten, and
wherein the third metal layer includes titanium.
